(19) United States
(12) Patent Application Publication
(10) Pub. No.: US 2009/0212332 A1
(43) Pub. Date: Aug. 27, 2009

(54) FIELD EFFECT TRANSISTOR WITH REDUCED OVERLAP CAPACITANCE

(75) Inventors: Xinlin Wang, Poughkeepsie, NY (US); Michael A. Gribelyuk, Stamford, CT (US); Wesley C. Natzle, New Paltz, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 12/034,941

(22) Filed: Feb. 21, 2008

(51) Int. Cl. H01L 29/00; H01L 21/336

(52) U.S. Cl. 257/288; 438/197; 257/E21.409; 257/E29.001

(57) ABSTRACT

In a first structure, a metal gate portion may be laterally recessed from a substantially vertical surface of a gate conductor thereabove. A cavity is formed between the metal gate portion and a gate spacer. In a second structure, a disposable gate portion is removed after laterally recessing a metal gate portion therebeneath and forming a dielectric layer having a surface coplanar with a top surface of the disposable gate portion. (We have to include the inner spacer without a metal recess). An inner gate spacer is formed over a periphery of the metal gate portion provide a reduced overlap capacitance. In a third structure, a thin dielectric layer is employed to form a cavity next to the metal gate portion in conjunction with the inner gate spacer to provide reduced overlap capacitance.

### FIELD OF THE INVENTION

The present invention relates to semiconductor structures, and particularly to semiconductor structures with reduced overlap capacitance between source/drain extensions and a gate electrode in a metal-oxide-semiconductor field effect transistor (MOSFET) and methods of manufacturing the same.

### BACKGROUND OF THE INVENTION

High gate-to-source/drain overlap capacitance in a metal-oxide-semiconductor field effect transistor (MOSFET) has an adverse effect on device performance. The gate-to-source/drain overlap capacitance, or more precisely, the overlap capacitance between the gate electrode and the source/drain extensions, has two components. The first component is the overlap capacitance between the gate electrode and the portions of the source/drain extensions under the gate dielectric. The second component is the overlap capacitance between the gate electrode and the portions of the source/drain extensions outside the overlap area with the gate electrode. The fringe electric fields at the edges of the gate electrode pass through a gate spacer, which comprises a dielectric material located on the sidewalls of the gate electrode, and capacitively couple the gate electrode with the source/drain extensions.

Referring to FIG. 1, a prior art MOSFET structure illustrates the two components of the overlap capacitance discussed above. The prior art MOSFET comprises a semiconductor substrate 108 including a body portion 110, a source extension region 132, a drain extension region 134, a source region 142, and a drain regions 144. A gate electrode 166 comprising a stack of a gate dielectric 120 and a gate conductor 126 is disposed on the body portion 110 such that the gate conductor 126 overlies portions of the source and drain extensions 132. A gate spacer 140 and a gate silicide 156 are located on the gate conductor 126. Typically, a source side silicide 152 and a drain side silicide 154 are located on the source region 142 and the drain regions 144, respectively. The overlap capacitance includes a first overlap capacitance component which is a capacitance between the gate conductor 166 and the source extension region 132 and the drain extension region 134 directly through the gate dielectric 120, and a second component which is a capacitance between the gate conductor 166 and the source extension region 132 and the drain extension region 134 through the gate spacer 140 and around the gate dielectric 120.

The effective oxide thickness (EOT) of the gate dielectric 120, having a small value from about 0.8 nm to about 6 nm, tends to increase the value of the first component. However, the overlap area between the gate conductor 166 and the source and drain extension regions (132, 134) is relatively small. For example, the overlap area typically has a length of less than 10 nm. The dielectric constant of a gate dielectric 120 has a relatively low value of about 3.9 in the case of a silicon oxide gate dielectric. Alternately, the physical thickness of a high dielectric constant (high-k) material employed in a gate electrode 120 is thicker than a corresponding gate dielectric 120 of the same EOT, so that the first component of the capacitance is the same for the same EOT and the same overlap area. These factors help limit the first component of the overlap capacitance.

As for the second component of the overlap capacitance, the average distance between the gate conductor 166 and the source and drain extension regions (132, 134) is greater than the thickness of the gate dielectric 120. However, large surface areas of a parasitic capacitor structure, that is, the entire sidewall surface area of the gate conductor 166 adjacent to the source and drain extension regions (132, 134) and the area of the source and drain extension regions (132, 134) outside the directly overlapped area under the gate conductor 166, are involved in the capacitive coupling. Further, silicon nitride, which is typically employed for the gate spacer 140 has a relatively high dielectric constant of about 7.5. Compared with the dielectric constant of about 3.9 for silicon oxide, the higher dielectric constant of silicon nitride contributes to a substantial value in the second component of the overlap capacitance.

The replacement of the silicon nitride second spacer with a silicon oxide second spacer may be achieved to reduce the second component of the overlap capacitance, as is known in the prior art. Even in this case, however, the second component of the overlap capacitance still may be substantial.

Therefore, there exists a need to provide a semiconductor structure with a reduced overlap capacitance between a gate electrode and source/drain extensions, and methods of manufacturing the same.

### SUMMARY OF THE INVENTION

The present invention addresses the needs described above by providing semiconductor structures having a reduced overlap capacitance between a gate electrode and source and drain extension regions, and methods of manufacturing the same.

In a first structure, a metal gate portion directly above a gate dielectric is recessed inward from a substantially vertical surface of a gate conductor thereabove. The gate spacer is formed in a non-conformal or directional deposition so that a cavity is formed directly on a sidewall of a metal gate portion.

In a second structure, a disposable gate portion is formed on a metal gate portion, which is thereafter optionally laterally recessed. The disposable gate portion is subsequently removed after forming a dielectric layer having a surface coplanar with a top surface of the disposable gate portion. An inner gate spacer is formed over the metal gate portion and a gate conductor abutting only a center portion of the metal gate portion is formed to provide a reduced overlap capacitance.

In a third structure, a thin dielectric layer may be employed to form a cavity next to the metal gate portion in conjunction with the inner gate spacer to provide reduced overlap capacitance.

According to an aspect of the present invention, a metal-oxide-semiconductor field effect transistor (MOSFET) structure is provided, which comprises:

a gate dielectric abutting and overlying a body portion, a source extension region, and a drain extension region in a semiconductor substrate;

a metal gate portion vertically abutting the gate dielectric portion;

a gate conductor vertically abutting the metal gate portion;

a gate spacer comprising a dielectric material and laterally abutting the gate conductor and vertically abutting the source extension region or the drain extension region; and

a cavity enclosed by the metal gate portion, the gate dielectric, the gate conductor, and the gate spacer.

In one embodiment, the gate conductor directly overlies an entirety of the cavity.

In another embodiment, sidewalls of the metal gate portion and sidewalls of the gate dielectric are substantially vertically coincident and offset from sidewalls of the gate conductor.

In yet another embodiment, the cavity separates the gate spacer from the metal gate portion and the gate dielectric.

In still another embodiment, sidewalls of the gate conductor and sidewalls of the gate dielectric are substantially vertically coincident and offset from sidewalls of the metal gate portion.

According to another aspect of the present invention, another metal-oxide-semiconductor field effect transistor (MOSFET) structure is provided, which comprises:

a gate dielectric abutting and overlying a body portion, a source extension region, and a drain extension region in a semiconductor substrate;

a metal gate portion vertically abutting the gate dielectric portion;

a dielectric liner vertically abutting the source extension region or the drain extension region and laterally abutting the gate dielectric and the metal gate portion; and

an inner gate spacer overlying an entire periphery of the metal gate portion.

The inner gate spacer may abut the entire periphery of the metal gate portion. The inner gate spacer may abut and overlie a surface of the dielectric liner which is substantially coplanar with a top surface of the metal gate portion. Substantially vertical outer sidewalls of the inner gate spacer may laterally abut substantially vertical portion of the dielectric liner.

In one embodiment, the dielectric liner comprises:

a first horizontal dielectric liner portion vertically abutting the source extension region or the drain extension region;

a first vertical dielectric liner portion laterally abutting the gate dielectric and the metal gate portion;

a second horizontal dielectric liner portion directly adjoined to the first vertical dielectric liner portion and abutting a bottom surface of the inner gate spacer; and

a second vertical dielectric liner portion directly adjoined to the second horizontal dielectric liner portion and abutting a substantially vertical sidewall of the inner gate spacer.

In another embodiment, the MOSFET structure further comprises:

a gate conductor vertically abutting the metal gate portion; and

a gate spacer comprising a dielectric material, overlying the source extension region or the drain extension region, and abutting the dielectric liner.

In yet another embodiment, the MOSFET structure further comprises a cavity enclosed by the gate spacer and the dielectric liner.

In still another embodiment, sidewalls of the metal gate portion and sidewalls of the gate dielectric are substantially vertically coincident and offset from sidewalls of the gate conductor.

According to yet another aspect of the present invention, yet another metal-oxide-semiconductor field effect transistor (MOSFET) structure is provided which comprises:

a gate dielectric abutting and overlying a body portion, a source extension region, and a drain extension region in a semiconductor substrate;

a metal gate portion vertically abutting the gate dielectric portion;

a gate spacer vertically abutting the source extension region or the drain extension region and laterally abutting the gate dielectric and the metal gate portion; and

an inner gate spacer overlying an entire periphery of the metal gate portion.

The inner gate spacer may abut the entire periphery of the metal gate portion. The inner gate spacer may abut and overlie a surface of the dielectric liner which is substantially coplanar with a top surface of the metal gate portion. Substantially vertical outer sidewalls of the inner gate spacer may laterally abut substantially vertical inner sidewalls of the gate spacer.

In one embodiment, the MOSFET structure further comprises:

a gate conductor vertically abutting the metal gate portion; and

a gate spacer comprising a dielectric material, vertically abutting the source extension region or the drain extension region, and laterally abutting the dielectric liner.

In another embodiment, sidewalls of the metal gate portion and sidewalls of the gate dielectric are substantially vertically coincident and offset from sidewalls of the inner gate spacer.

In yet another embodiment, a bottom surface of the inner gate spacer overlies an entire periphery of the metal gate portion.

In still another embodiment, the gate spacer comprises:

a first horizontal gate spacer surface vertically abutting the source extension region or the drain extension region;

a first vertical gate spacer surface laterally abutting the gate dielectric and the metal gate portion;

a second horizontal gate spacer surface directly adjoined to the first vertical gate spacer surface and abutting a bottom surface of the inner gate spacer; and

a second vertical gate spacer surface directly adjoined to the second horizontal gate spacer surface and abutting a substantially vertical sidewall of the inner gate spacer.

According to even another aspect of the present invention, even another metal-oxide-semiconductor field effect transistor (MOSFET) structure is provided which comprises:

a gate dielectric abutting and overlying a body portion, a source extension region, and a drain extension region in a semiconductor substrate;

a metal gate portion vertically abutting the gate dielectric portion;

a gate spacer vertically abutting the source extension region or the drain extension region and laterally abutting the gate dielectric and the metal gate portion; and

an inner gate spacer overlying the metal gate portion, wherein an entirety of periphery of the inner gate spacer is vertically coincident with an entire periphery of the metal gate portion.

An entirety of sidewalls of the metal gate portion is vertically coincident with and entirety of sidewalls of the gate dielectric and an entirety of substantially vertical sidewalls of the inner gate spacer.

The MOSFET structure may further comprise an L-shaped dielectric liner which laterally abuts an outer sidewall of the inner gate spacer and an inner sidewall of the gate spacer.

According to still another aspect of the preset invention, a method of forming a semiconductor structure is provided, which comprises:

forming a stack of a gate dielectric, a metal gate portion, and one of a gate conductor and a disposable gate portion on a semiconductor substrate, wherein sidewalls of the gate dielectric, the metal gate portion, and one of the gate conductor and the disposable gate portion are substantially vertically coincident;

laterally recessing a sidewall of the metal gate portion relative to a sidewall of the one of the gate conductor and the disposable gate portion;

forming a source extension region and a drain extension region underlying the metal gate portion; and

forming a gate spacer on the gate dielectric, the one of the gate conductor and the disposable gate portion, the source extension region, and the drain extension region.

In one embodiment, the method further comprises forming a cavity encapsulated by the gate dielectric, the metal gate portion, the gate spacer, and the gate conductor, wherein the gate spacer is formed directly on the gate dielectric, the one of the gate conductor and the disposable gate portion, the source extension region, and the drain extension region.

In another embodiment, the method further comprises:

forming a dielectric liner laterally abutting the gate dielectric, the metal gate portion, and the disposable gate portion; and

forming a cavity encapsulated by the dielectric liner and the gate spacer, wherein the disposable gate portion overlies an entirety of the cavity.

In yet another embodiment, the method further comprises:

forming a dielectric layer over the disposable gate portion;

planarizing the dielectric layer, wherein a top surface of the dielectric layer is substantially coplanar with a top surface of the disposable gate portion;

removing the gate disposable gate portion;

forming an inner gate spacer overlying an entire periphery of the metal gate portion, wherein a sidewall of the metal gate portion directly adjoins a bottom surface of the inner gate spacer; and

forming a conductive gate portion directly on the metal gate portion.

In still another embodiment, the gate spacer is formed directly on the gate dielectric, the metal gate portion, the one of the gate conductor and the disposable gate portion, the source extension region, and the drain extension region. The method further comprises:

forming a dielectric layer over the disposable gate portion;

planarizing the dielectric layer, wherein a top surface of the dielectric layer is substantially coplanar with a top surface of the disposable gate portion;

removing the gate disposable gate portion;

forming an inner gate spacer overlying an entire periphery of the metal gate portion, wherein a sidewall of the metal gate portion directly adjoins a bottom surface of the inner gate spacer; and

forming a conductive gate portion directly on the metal gate portion.

### BRIEF DESCRIPTION OF THE DRAWINGS

FIG. 1 is a vertical cross-sectional view of an exemplary prior art MOSFET structure, which illustrates two components of the overlap capacitance between a gate electrode and source and drain extension regions.

FIGS. 2, 3, 4, and 5 are sequential vertical cross-sectional views of a first exemplary semiconductor structures at various stages of a manufacturing process according to a first embodiment of the present invention.

FIG. 3A is a first variation of the first exemplary semiconductor structures at a step corresponding to FIG. 3. FIGS. 5A and 5B are first and second variations, respectively, of the first exemplary semiconductor structures at a step corresponding to FIG. 5.

FIGS. 6-14 are sequential vertical cross-sectional views of a second exemplary semiconductor structures at various stages of a manufacturing process according to a second embodiment of the present invention. FIG. 9A is a magnified view of a dielectric liner 38 of FIG. 9.

FIG. 14A is a variation of the second exemplary semiconductor structures at a step corresponding to FIG. 14.

FIGS. 15-20 are sequential vertical cross-sectional views of a third exemplary semiconductor structures at various stages of a manufacturing process according to a third embodiment of the present invention.

FIG. 21 is a first variation of the third exemplary semiconductor structures at a step corresponding to FIG. 20.

FIG. 22 is a second variation of the third exemplary semiconductor structures at a step corresponding to FIG. 20.

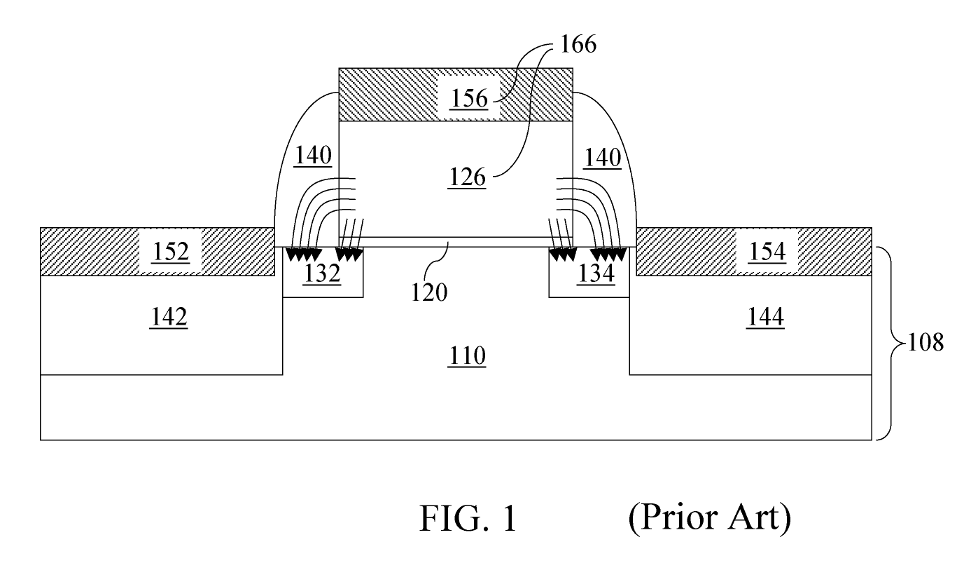

### DETAILED DESCRIPTION OF THE INVENTION

As stated above, the present invention relates to semiconductor structures with reduced overlap capacitance between source/drain extensions and a gate electrode in a metal-oxide-semiconductor field effect transistor (MOSFET) and methods of manufacturing the same, which are now described in detail with accompanying figures. It is noted that like and corresponding elements are referred to by like reference numerals.

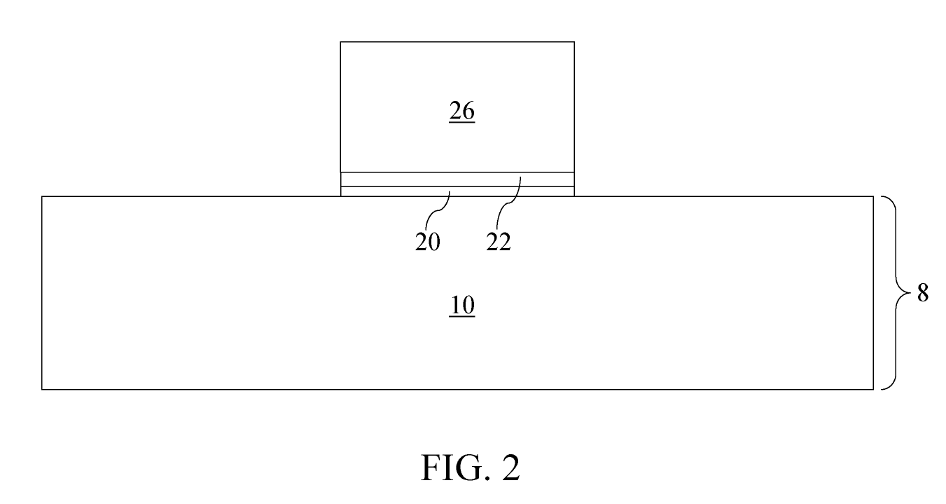

Referring to FIG. 2, a first exemplary semiconductor structure according to the present invention is shown, which comprises a semiconductor substrate 8 containing a semiconductor layer 10, a gate dielectric 20 formed on the semiconductor layer 10, a metal gate portion 22 formed on the gate dielectric 20, and a gate conductor 26 formed on the metal gate portion 22. Preferably, the semiconductor layer 10 comprises a single crystalline semiconductor material. The semiconductor material may be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Typically, the semiconductor material comprises silicon. The semiconductor layer 10 is typically lightly doped, i.e., have a dopant concentration from about 1.0×10¹⁵/cm³ to about 3.0×10¹⁸/cm³, and preferably from about 1.0×10¹⁵/cm³ to about 3.0×10¹⁷/cm³, although lesser and greater dopant concentrations are explicitly contemplated herein. The semiconductor substrate 8 may be a bulk substrate, a semiconductor-on-insulator (SOI) substrate, or a hybrid substrate. The semiconductor substrate 8 may have a built-in stress in the semiconductor layer 10. While the present invention is described with a bulk substrate, implementation of the present invention on an SOI substrate or on a hybrid substrate is explicitly contemplated herein.

The gate dielectric 20, the metal gate portion 22, and the gate conductor 26 are formed by formation of a stack of a gate dielectric layer, a metal gate layer, and a gate conductor layer, followed by a lithographic patterning and an anisotropic ion etch that transfers the pattern into the stack. The remaining portion of the stack constitutes the gate dielectric 20, the metal gate portion 22, and the gate conductor 26. Each of the sidewalls of the gate dielectric 20, the metal gate portion 22, and the gate conductor 26 are substantially vertical, and substantially vertically coincident among one another. The width, or the lateral dimension, of a gate stack comprising gate dielectric 20, the metal gate portion 22, and the gate conductor 26 is determined by the desired channel length, which may be from about 20 nm to about 100 nm, and scales with advances in semiconductor processing technology.

Preferably, the gate dielectric 20 comprises a high dielectric constant (high-k) material comprising a dielectric metal oxide and having a dielectric constant that is greater than the dielectric constant of silicon nitride of 7.5. The gate dielectric 20 may be formed by methods well known in the art including, for example, chemical vapor deposition (CVD), atomic layer deposition (ALD), molecular beam deposition (MBD), pulsed laser deposition (PLD), liquid source misted chemical deposition (LSMCD), etc. The dielectric metal oxide comprises a metal and oxygen, and optionally nitrogen and/or silicon. Exemplary high-k dielectric materials include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from about 0.5 to about 3 and each value of y is independently from 0 to about 2. The thickness of the gate dielectric 20 may be from about 1 nm to about 10 nm, and preferably from about 1.5 nm to about 3 nm. The gate dielectric 20 may have an effective oxide thickness (EOT) on the order of, or less than, 1 nm. The gate dielectric 20 may optionally include an interfacial layer (not shown) between the portion of the high-k dielectric material and the semiconductor layer 10. The interfacial layer, which preferably comprises silicon oxide or silicon oxynitride, helps minimize mobility degradation due to high-k dielectric material.

The metal gate layer, out of which the metal gate portion 22 is patterned, is formed, for example, by chemical vapor deposition (CVD), physical vapor deposition (PVD), atomic layer deposition (ALD), etc. The metal gate portion 22 comprises a metallic material which may comprise an elemental metal, a metal alloy, a conductive metal oxide, and/or a conductive metal nitride. Non-limiting exemplary materials for the metal gate portion include Ru, Pd, Pt, Co, Ni, TaₓAl_{y}N, WₓC_{y}N, Zr, W, Ta, Hf, Ti, Al, a metal carbide, a transition metal aluminide, a conductive metal oxide, and a combination thereof. Each value of x is independently from 0 to about 1 and each value of y is independently from 0 to about 1. Exemplary transition metal aluminides include Ti₃Al and ZrAl. The thickness of the metal gate portion 22 may be from about 2 nm to about 30 nm, and preferably from about 3 nm to about 10 nm, although lesser and greater thicknesses are contemplated herein also. Preferably, the composition of the metal gate portion 22 and the work function of the metal gate portion 22, is selected to optimize the threshold voltage of a transistor to be subsequently formed.

The gate conductor layer, out of which the gate conductor 26 is patterned, may be formed by chemical vapor deposition (CVD) such as low pressure chemical vapor deposition (LPCVD), rapid thermal chemical vapor deposition (RTCVD), plasma enhanced chemical vapor deposition (PECVD), etc. The gate conductor 26 comprises a semiconductor material or a metallic material. In case the gate conductor 26 comprises a semiconductor material, the gate conductor 26 may be amorphous or polycrystalline. Non-limiting exemplary materials for the disposable material layer 34L include silicon, germanium, a silicon-germanium alloy, a silicon carbon alloy, a silicon-germanium-carbon alloy, gallium arsenide, indium arsenide, indium phosphide, III-V compound semiconductor materials, II-VI compound semiconductor materials, organic semiconductor materials, and other compound semiconductor materials. The thickness of the gate conductor 26 may be from about 10 nm to about 200 nm, and typically from about 50 nm to about 120 nm, although lesser and greater thicknesses are also explicitly contemplated herein. Note that in most cases the gate conductor 26 will be a metal or semiconductor, but it is understood by those skilled in the art that the material could even be an insulator in the embodiments where 26 is disposable. In these embodiments, 26 represents a structure which, in subsequent steps, is first removed then substituted entirely or in part by a gate conductor.

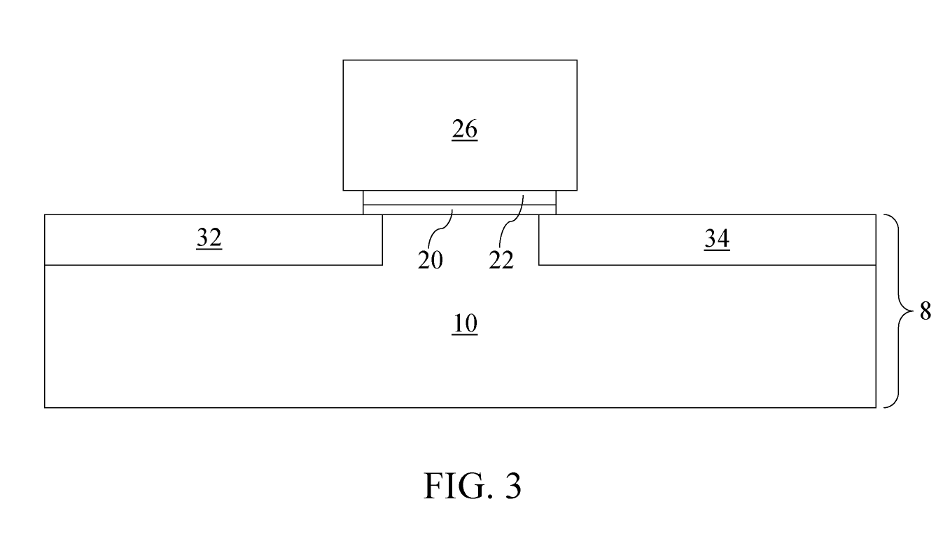

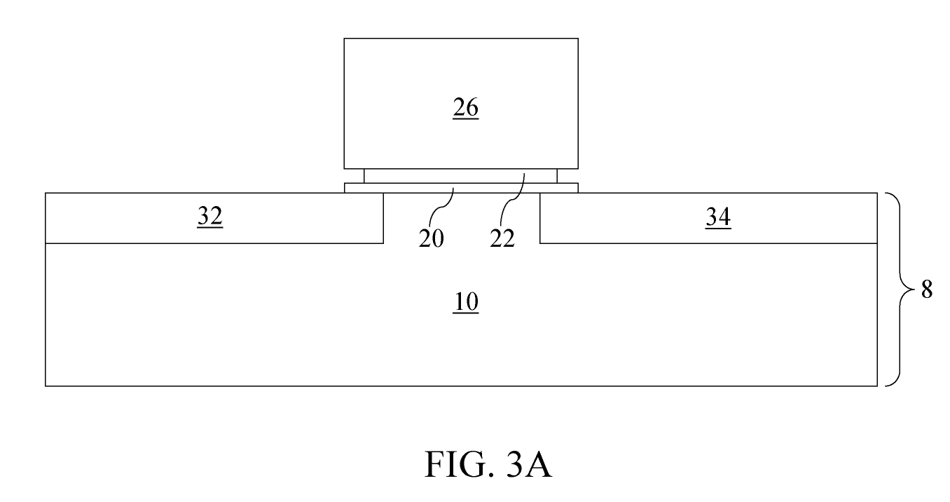

Referring to FIG. 3, the metal gate portion 22 and the gate dielectric 20 are laterally recessed selective to the gate conductor 26. The distance of the lateral recess may be from about 0.5 nm to about 10 nm, and typically from about 1 nm to about 5 nm, although lesser and greater distances are contemplated herein also. Preferably, the sidewalls of the metal gate portion 22 and the gate dielectric 20 are substantially vertically coincident after the lateral recess, and are offset from the sidewalls of the gate conductor 26 by the distance of the lateral offset.

A source extension region 32 and a drain extension region 34 are formed in the semiconductor substrate 8 by implanting dopants into exposed portions of the semiconductor layer 10. Typically, the source and drain extension regions (32, 34) are formed by implanting dopants of the opposite conductivity type than the conductivity type of the semiconductor layer 10. For example, if the semiconductor layer 10 has a p-type doping, the source and drain extension regions (32, 34) have an n-type doping, and vice versa. The source and drain extension regions (32, 34) have a dopant concentration from about 1.0×10¹⁹/cm³ to about 1.0×10²¹/cm³, and preferably from about 3.0×10¹⁹/cm³ to about 5.0×10²⁰/cm³, although lesser and greater dopant concentrations are contemplated herein. The source and drain extension regions (32, 34) overlap, i.e., directly contact, peripheral portions of the gate dielectric 20.

Referring to FIG. 3A, a first variation on the first exemplary semiconductor structure is shown, which is formed from the first exemplary semiconductor structure of FIG. 2 by laterally recessing selective to the gate conductor 26 and the gate dielectric 20. The distance of the lateral recess may be from about 0.5 nm to about 10 nm, and typically from about 1 nm to about 5 nm, although lesser and greater distances are contemplated herein also. In contrast to the structure of FIG. 3, the gate dielectric 20 is not laterally recessed. Preferably, the sidewalls of the gate conductor 26 and the gate dielectric 20 are substantially vertically coincident after the lateral recess. The sidewalls of the metal gate portion 22 are offset from the sidewalls of the gate conductor 26 by the distance of the lateral offset.

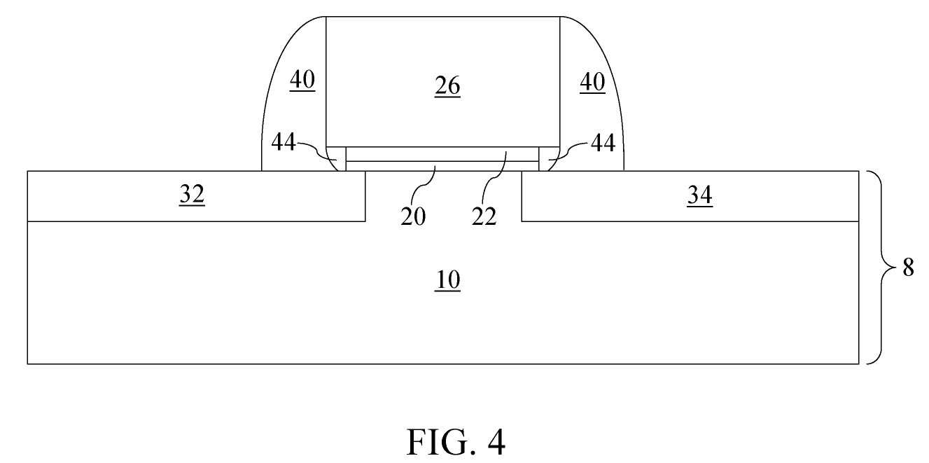

Referring to FIG. 4, a gate spacer 40 is formed by deposition of a dielectric material and an anisotropic etch, such as a reactive ion etch, thereof. The dielectric material is deposited in a deposition process that is not completely conformal. Such incomplete conformity of deposition may be effected by an anisotropic deposition in which the amount of deposition depends on the orientation of a surface, aspect ratio, and/or shading. Such non-conformal deposition process typically occurs when deposition rate is not temperature-limited, but is reactant-limited as in plasma enhanced chemical vapor deposition (PECVD), high density plasma chemical vapor deposition (HDPCVD), or rapid thermal chemical vapor deposition (RTCVD).

The overhanging and laterally protruding portion of the gate conductor 26 outside of the sidewalls of the metal gate portion 22 and the gate dielectric 20 shades the area of the semiconductor substrate 8 underneath the overhanging and laterally protruding portion of the gate conductor 26. Thus, a cavity 44 is formed between the gate spacer 40 and the stack of the metal gate portion 22 and the gate dielectric 20. The gate conductor 26 typically forms a contiguous block. Thus, the gate spacer 40 typically laterally surrounds and encloses the gate conductor 26. Since the gate spacer 40 also abuts the top surfaces of the semiconductor substrate 8, e.g., a top surface of the source extension region 32 and a top surface of the drain extension region 34, the cavity 44 is encapsulated by the semiconductor substrate 8, the gate spacer 40, the gate conductor 26, and the stack of the metal gate portion 22 and the gate dielectric 20. Typically, the cavity 44 is topologically homeomorphic to a torus, i.e., has a shape of a doughnut, since the cavity 44 laterally surrounds the stack of the metal gate portion 22 and the gate dielectric 20.

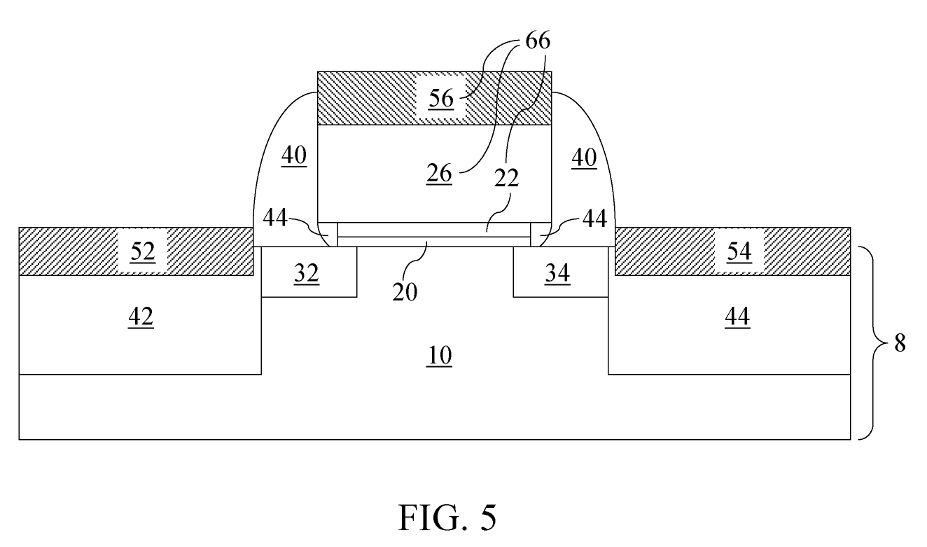

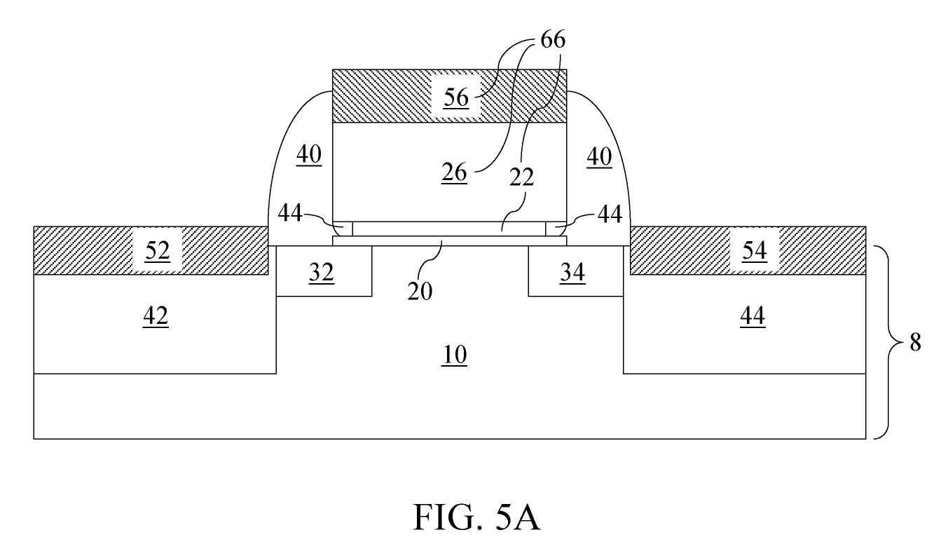

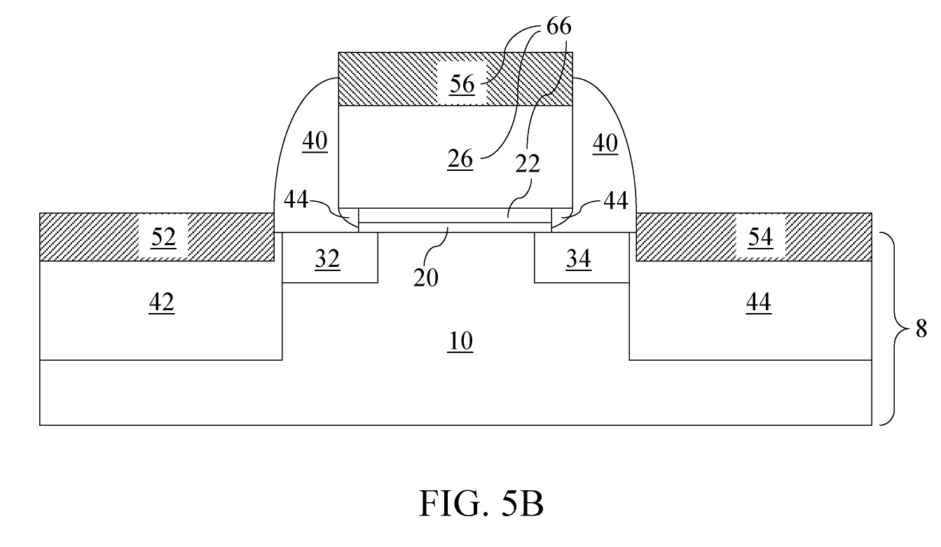

Referring to FIG. 5, a source region 42 and the drain region 44 are formed in the semiconductor layer 10 by ion implantation. Typically, the source region 42 and the drain region 44 have the same conductivity type as the source and drain extension regions (32, 34), and may have a doping concentration from about 3.0×10¹⁹/cm³ to about 1.0×10²¹/cm³, and preferably from about 1.0×10²⁰/cm³ to about 5.0×10²⁰/cm³, although lesser and greater dopant concentrations are contemplated herein. A source side metal semiconductor alloy portion 52, a drain side metal semiconductor alloy portion 54, and a gate metal semiconductor alloy portion 56 are formed on the source region 42, the drain region 44, and the conductor 26 by reacting a metal with exposed portions of the semiconductor materials in the semiconductor substrate 8 and the gate conductor 26. The metal gate portion 22, the gate conductor 26, and the gate metal semiconductor alloy portion 56 collectively constitutes a gate electrode 66. The gate electrode 66 overlies the entirety of the cavity 44.

The cavity 44 between the source and drain extension regions (32, 34) and the conductive gate portion 86 has a dielectric constant of vacuum or air, which is equal to, or substantially equal to 1. Thus, the first exemplary semiconductor structure provides reduction in overlap capacitance between the gate electrode 66 and the source and drain extension regions (32, 34).

Referring to FIG. 5A, the first variation on the first exemplary semiconductor structure is shown, in which the sidewalls of the gate conductor 26 and the gate dielectric 20 are substantially vertically coincident and the sidewalls of the metal gate portion 22 are offset from the sidewalls of the gate conductor 26 by the distance of the lateral offset. The cavity 44 is encapsulated by the gate spacer 40, the gate conductor 26, and the stack of the metal gate portion 22 and the gate dielectric 20. The cavity 44 is separated from the semiconductor substrate 8 by the gate dielectric 20.

Referring to FIG. 5B, a second variation on the first exemplary semiconductor structure is shown, in which the gate spacer 40 and the gate dielectric 20 covers all of the surfaces of the semiconductor substrate 8 underlying the gate conductor 26. This structure is formed when the conformity of the deposition process employed to form the gate spacer 40 increases at the processing step of FIG. 4. In this case, the cavity 44 is encapsulated by the gate spacer 40, the gate conductor 26, and the stack of the metal gate portion 22 and the gate dielectric 20. The cavity 44 is separated from the semiconductor substrate 8 by a bottom portion of the gate spacer 40, which abuts sidewalls of the gate dielectric 20.

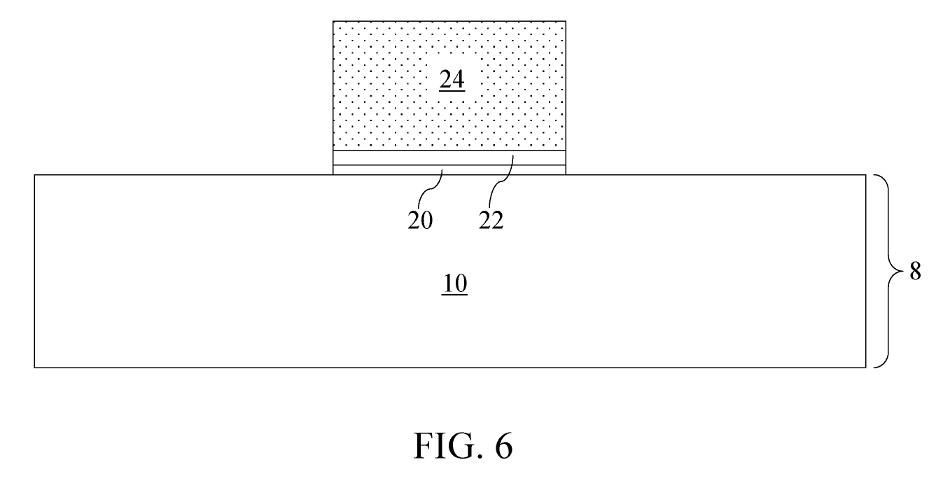

Referring to FIG. 6, a second exemplary semiconductor structure according to a second embodiment of the present invention comprises a semiconductor substrate 8 containing a semiconductor layer 10, a gate dielectric 20 formed on the semiconductor layer 10, a metal gate portion 22 formed on the gate dielectric 20, and a disposable gate portion 24 formed on the metal gate portion. The stack of the gate dielectric 20, the metal gate portion 22, and the disposable gate portion 24 is formed in a manner similar to the formation of the stack of the gate dielectric 20, the metal gate portion 22, and the gate conductor 26 in the first embodiment except that a disposable material layer (not shown) is employed in lieu of the gate conductor layer so that the disposable gate portion 24 is formed in the second exemplary semiconductor structure instead of the gate conductor 26 in the first exemplary semiconductor structure.

A disposable material layer is formed directly on the metal gate layer by chemical vapor deposition (CVD) such as low pressure chemical vapor deposition (LPCVD), rapid thermal chemical vapor deposition (RTCVD), plasma enhanced chemical vapor deposition (PECVD), etc. The disposable material layer may comprise a semiconductor material, a metallic material, or a dielectric material. The disposable material layer comprises a material that may be removed selective to a dielectric material of a gate spacer and a dielectric layer to be subsequently formed. In case the disposable material layer comprises a semiconductor material, the disposable material layer may be amorphous or polycrystalline. Non-limiting exemplary materials for the disposable material layer include silicon, germanium, a silicon-germanium alloy, a silicon carbon alloy, a silicon-germanium-carbon alloy, gallium arsenide, indium arsenide, indium phosphide, III-V compound semiconductor materials, II-VI compound semiconductor materials, organic semiconductor materials, and other compound semiconductor materials. In case the disposable material layer comprises a dielectric material, the disposable material layer may comprise a porous or non-porous dielectric material that may be easily etched selective to the first metallic material. The thickness of the disposable material layer may be from about 10 nm to about 150 nm, and typically from about 50 nm to about 120 nm, although lesser and greater thicknesses are also explicitly contemplated herein. The disposable gate portion 24 has the same composition as, and substantially the same thickness as, the disposable material layer.

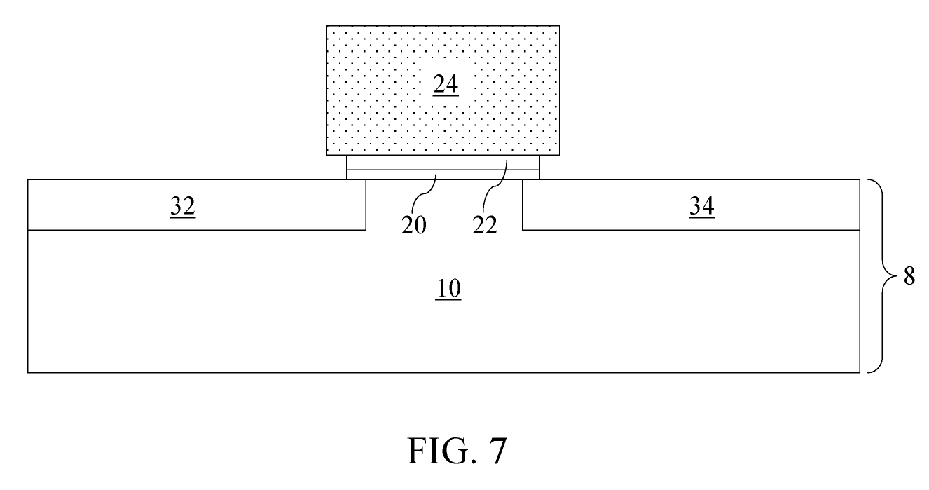

Referring to FIG. 7, the metal gate portion 22 and the gate dielectric 20 are laterally recessed selective to the disposable gate portion 24. The distance of the lateral recess may be from about 0.5 nm to about 10 nm, and typically from about 1 nm to about 5 nm, although lesser and greater distances are contemplated herein also. Preferably, the sidewalls of the metal gate portion 22 and the gate dielectric 20 are substantially vertically coincident after the lateral recess, and are offset from the sidewalls of the disposable gate portion 24 by the distance of the lateral offset.

A source extension region 32 and a drain extension region 34 are formed in the semiconductor substrate 8 by implanting dopants into exposed portions of the semiconductor layer 10 in the same manner as described above. The source and drain extension regions (32, 34) overlap, i.e., directly contact, peripheral portions of the gate dielectric 20.

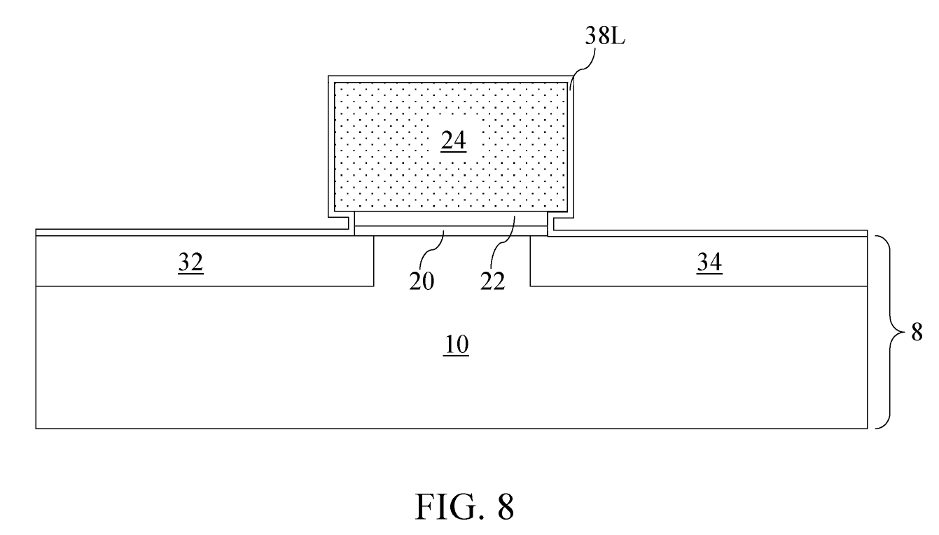

Referring to FIG. 8, a dielectric liner layer 38L is formed on all exposed surfaces of the second exemplary semiconductor structure by a conformal deposition of a dielectric material and/or a by a conformal component of the deposition of gate spacer 40. The dielectric liner layer 38L may comprises a dielectric nitride or a dielectric oxide. For example, the dielectric liner layer 38L may comprise silicon. The thickness of the dielectric liner layer 38 is substantially the same irrespective of the location of measurement of the thickness. The thickness of the dielectric liner layer 38L is less than one half of the sum of the thickness of the stack of the gate dielectric 20 and the metal gate portion so that the gap between the overhanging portions of the disposable gate portion and the semiconductor substrate 8 is not filled by the dielectric liner layer 38L. The thickness of the dielectric liner layer 38L may be from about 0.3 nm to about 4 nm, and typically from about 0.5 nm to about 2 nm, although lesser and greater thicknesses are contemplated herein also.

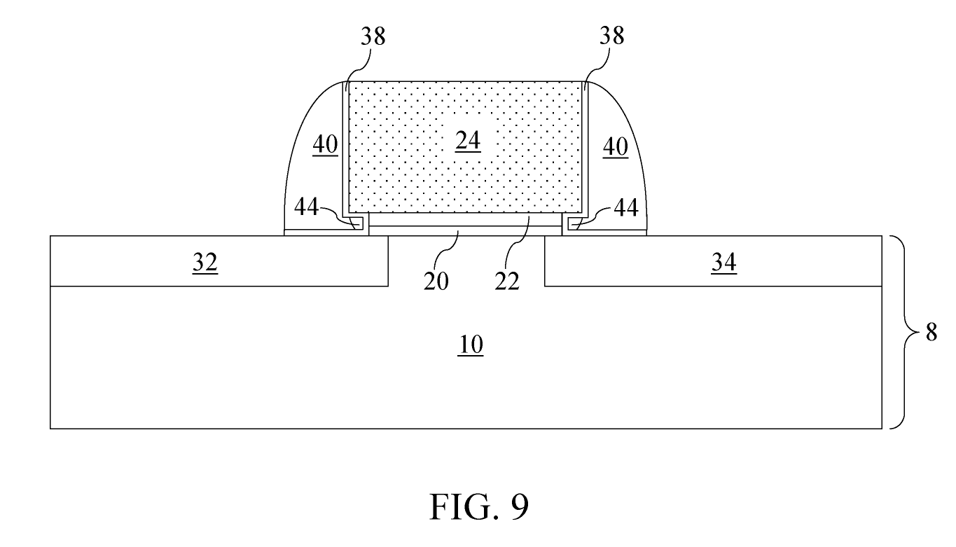

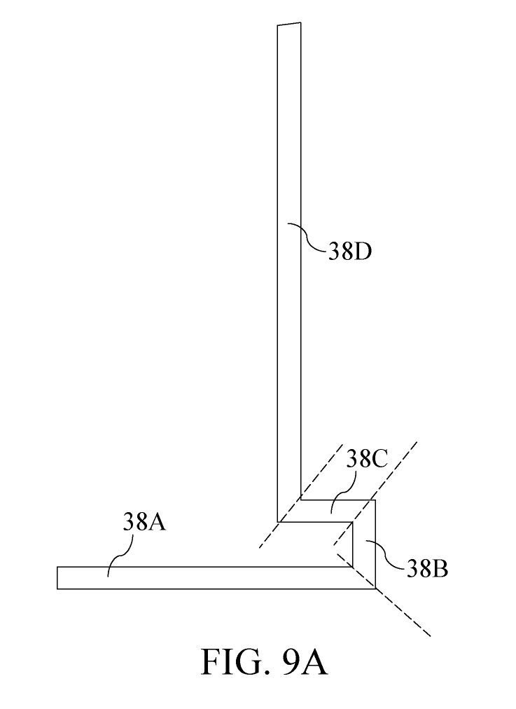

The second exemplary semiconductor structure at a next processing step is shown in FIG. 9 and a magnified view of a dielectric liner is shown in FIG. 9A. A gate spacer 40 is formed by deposition of a dielectric material and an anisotropic etch, such as a reactive ion etch, thereof in the same manner employed in the first embodiment. Exposed horizontal portions of the dielectric liner layer 38L is removed, for example, from above the disposable gate portion 24 and exposed surfaces of the semiconductor substrate 8 outside the area covered by the disposable gate portion 24 and the gate spacer 40. The remaining portion of the dielectric liner layer 38L constitutes a dielectric liner 38, which laterally surrounds the disposable gate portion 24, the metal gate portion 22, and the gate dielectric 20. The dielectric liner 38 is contiguous and of unitary construction, i.e., is in the form of one contiguous structure, and is topologically homeomorphic to a torus.

The dielectric liner 38 comprises a first horizontal dielectric liner portion 38A, a first vertical dielectric liner portion 38B, a second horizontal dielectric liner portion 38C, and a second vertical dielectric liner portion 38D. The first horizontal dielectric liner portion 38A vertically abuts the source extension region 32 and the drain extension region 34. The first vertical dielectric liner portion 38B laterally abuts the gate dielectric 20 and the metal gate portion 22. The second horizontal dielectric liner portion 38C is directly adjoined to the first vertical dielectric liner portion 38B and abuts a bottom surface of the disposable gate portion 24. The second vertical dielectric liner portion 38D is directly adjoined to the second horizontal dielectric liner portion 38C and abuts sidewalls of the disposable gate portion 24.

Recessed gaps between the first horizontal dielectric liner portion 38A and the second horizontal dielectric liner portion 38C are shaded by overhanging and laterally protruding portion of the disposable gate portion 24 above of the sidewalls of the metal gate portion 22 and the second vertical dielectric liner portion 38D. Thus, a cavity 44 is formed in the recessed portion. The disposable gate portion 24 typically forms a contiguous block. The cavity 44 is encapsulated by the gate spacer 40, the first horizontal dielectric liner portion 38A, the first vertical dielectric liner portion 38B, and the second horizontal dielectric liner portion 38C. Typically, the cavity 44 is topologically homeomorphic to a torus, i.e., has a shape of a doughnut, since the cavity 44 laterally surrounds the stack of the metal gate portion 22 and the gate dielectric 20.

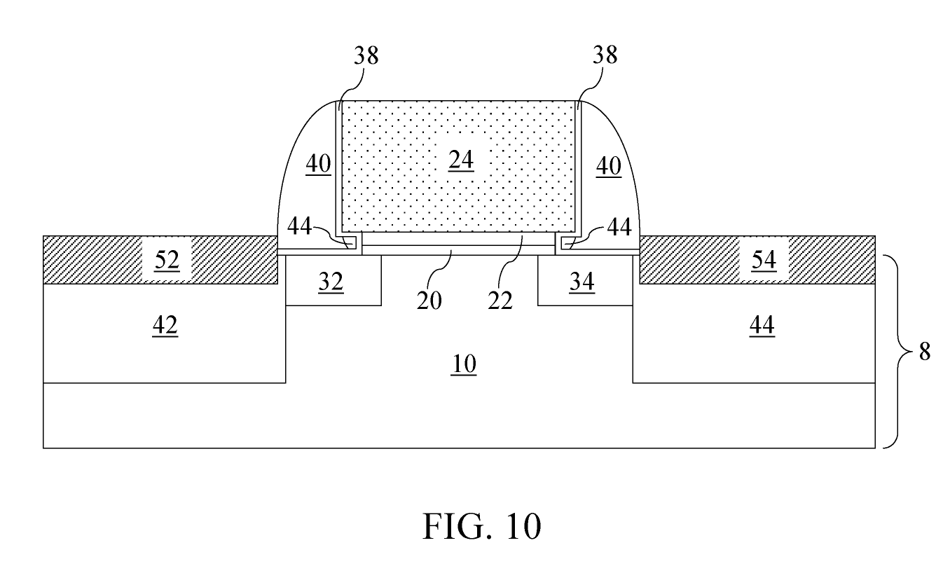

Referring to FIG. 10, a source region 42 and the drain region 44 are formed in the semiconductor layer 10 by ion implantation in the same manner as in the first embodiment. A source side metal semiconductor alloy portion 52 and a drain side metal semiconductor alloy portion 54 are formed on the source region 42 and the drain region 44, respectively, by reacting a metal with exposed portions of the semiconductor materials in the semiconductor substrate 8. Preferably, no metal semiconductor alloy portion is formed on the disposable gate portion 24, which may be effected by selection of material that does not form a metal semiconductor alloy for the disposable gate portion 24 or by masking of the disposable gate portion 24 to prevent formation of a metal semiconductor alloy thereupon.

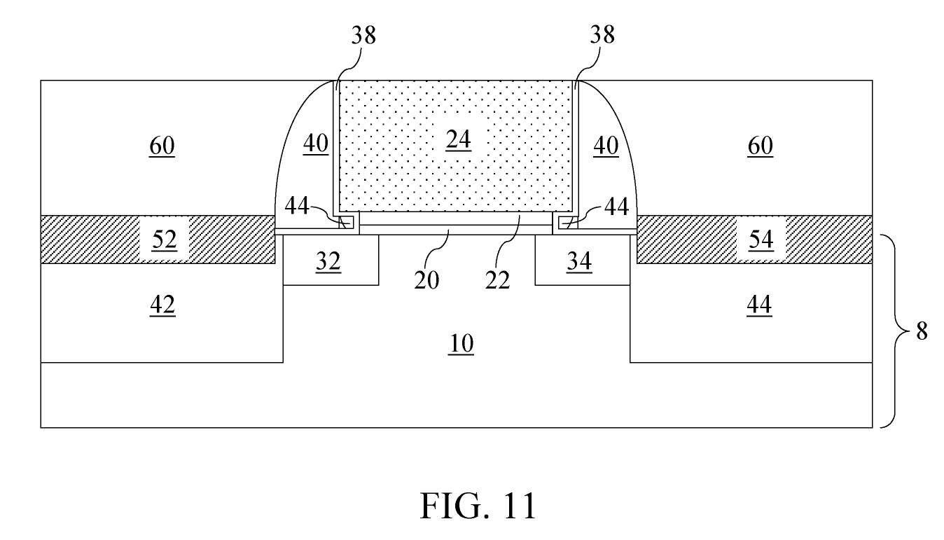

Referring to FIG. 11, a dielectric layer 60 is deposited over the entirety of the top surfaces of the second exemplary semiconductor structure, i.e., over the disposable gate portion 24, the gate spacer 40, the source side metal semiconductor alloy portion 52, and the drain side metal semiconductor alloy portion 54. The dielectric layer 60 comprises a dielectric material such as silicon oxide, silicon nitride, silicon oxynitride, or a combination thereof.

The dielectric layer 60 may, or may not, include a mobile ion barrier layer (not shown) which typically comprises an impervious dielectric material such as silicon nitride and directly contacts the source side and drain side metal semiconductor alloy portions (52, 54). The dielectric layer 60 may comprise, for example, a spin-on-glass and/or chemical vapor deposition (CVD) oxide such as undoped silicate glass (USG), borosilicate glass (BSG), phosphosilicate glass (PSG), fluorosilicate glass (FSG), borophosphosilicate glass (BPSG), or a combination thereof. Alternately, the dielectric layer 60 may comprise a low-k dielectric material having a dielectric constant less than 3.9 (the dielectric constant of silicon oxide), and preferably less than about 2.5. Exemplary low-k dielectric materials include organosilicate glass (OSG) and SiLK™.

The dielectric layer 60 is subsequently planarized to form a substantially planar top surface. Preferably, the disposable gate portion 24 is employed as a stopping layer. After the planarization processing step, the top surfaces of the disposable gate portion 24 is substantially coplanar with the top surface of the dielectric layer 60. In an alternative option, the dielectric layer 60 is planarized to the top of a liner dielectric (not shown) and a RIE step exposes the disposable gate portion 24. The thickness of the disposable gate portion 24 may be substantially the same as before the planarization processing step, or may be less than the thickness of the disposable gate portion 24 before the planarization processing step.

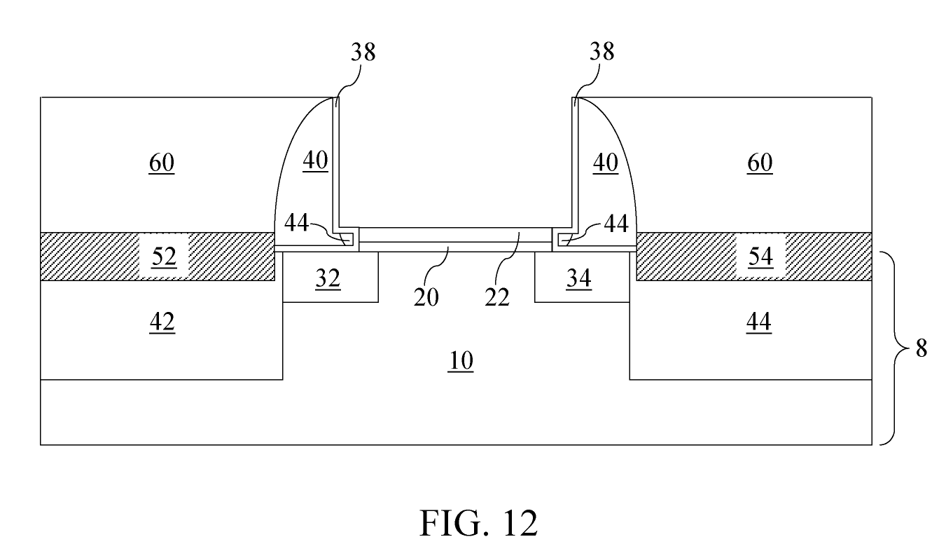

Referring to FIG. 12, the disposable gate portion 24 is removed by an etch that is selective to the materials of the dielectric layer 60, the dielectric liner 38, and the metal gate portion 22. The etch may be a wet etch or a dry etch, and the etch chemistry is optimized to achieve selectivity to the materials on the remaining exposed surfaces. Alternately, a disposable etch stop layer (not shown) may be formed after deposition of the metal gate portion 22 and before deposition of the disposable gate portion 24.

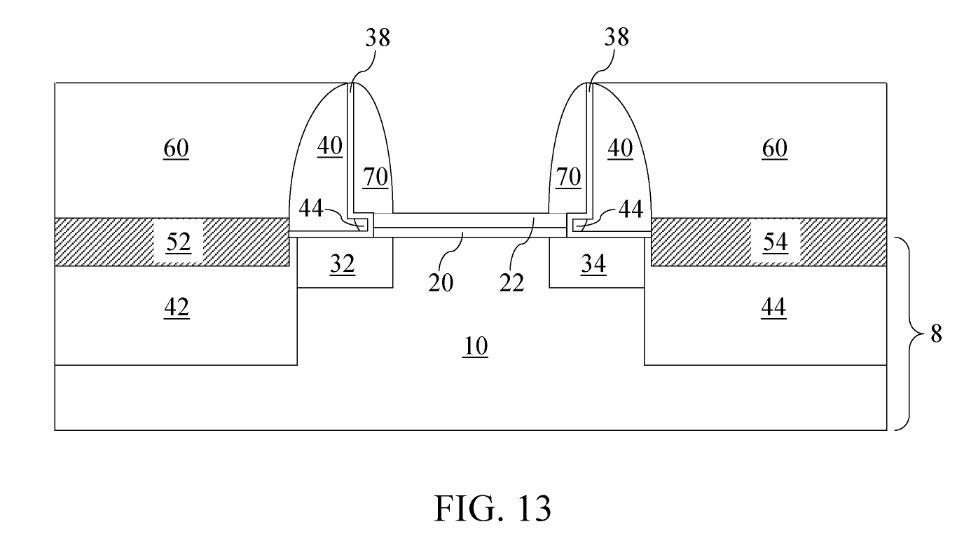

Referring to FIG. 13, an inner gate spacer 70 is formed by a substantially conformal deposition of a dielectric material, followed by a reactive ion etch. The inner gate spacer 70 may comprise the same material as, or a different material from, the gate spacer 40 or the dielectric liner 38. For example, the inner gate spacer 70 may comprise silicon oxide. The inner gate spacer 70 overlies the entire periphery of the metal gate portion 20. Further, the lateral width of the inner gate spacer 70, as measured at the bottom of the inner gate spacer 70, is greater than the lateral offset between the first vertical dielectric liner portion 38B and the second vertical dielectric liner portion 38D. The inner gate spacer 70 is of unitary construction. The inner gate spacer 70 laterally abuts, and is surrounded by, the second vertical dielectric liner portion 38D of the dielectric liner 38. The outer sidewalls of the inner gate spacer 70 are substantially vertical, and the inner sidewalls of the inner gate spacer 70 may have a convex curvature. The bottom portion of the inner sidewalls of the inner gate spacer 70 may be substantially vertical.

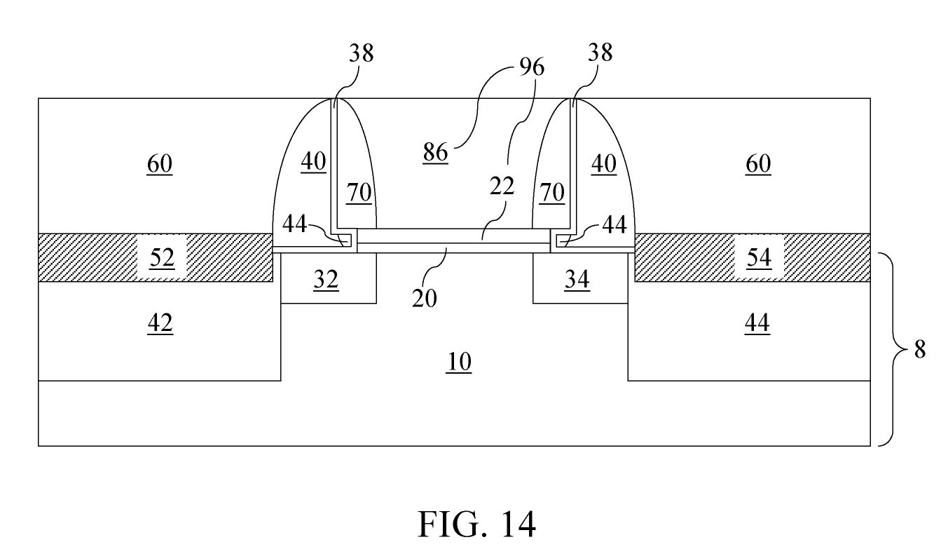

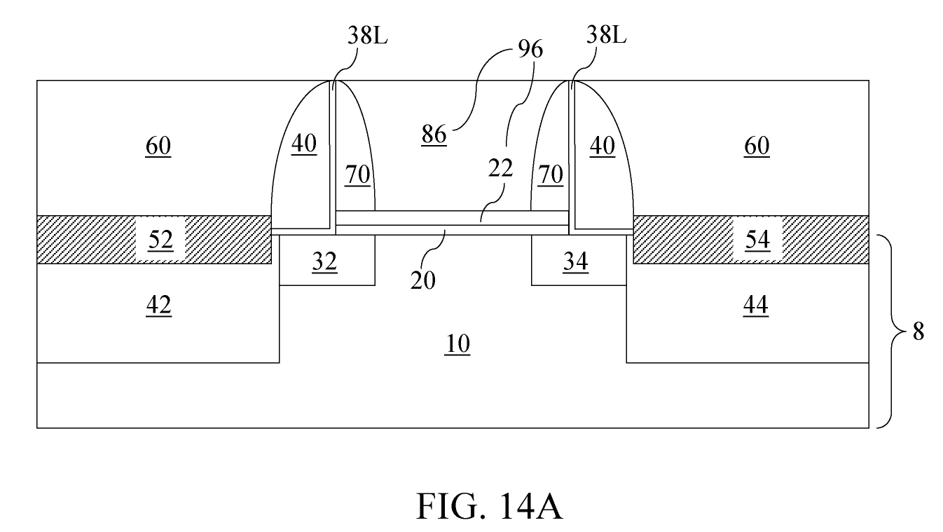

Referring to FIG. 14, a conductive gate portion 86 is formed directly on the metal gate portion 22 and the inner gate spacer 70 by deposition of a conductive material and planarization. The conductive material may comprise a doped semiconductor material or a metal. The conductive gate portion 86 may comprise any material that may be employed for the gate conductor 26 of the first exemplary semiconductor structure described above. The conductive material may be deposited by any method known in the art. The portion of the conductive material above the top surface of the dielectric layer 60 is removed by the planarization, such as chemical mechanical planarization (CMP) employing the dielectric layer 60 as a stopping layer. The conductive gate portion 86 and the metal gate portion 22 collectively constitute a gate electrode 96. The threshold voltage of the field effect transistor thus formed is determined by the work function of the metal gate portion 22 in addition to the dopant concentration, external stress, the material, and the crystallographic orientations of the semiconductor layer 11.

Due to the inner gate spacer 70, the distance between the source and drain extension regions (32, 34) and the conductive gate portion 86 is increased in comparison to prior art structures in which an inner gate spacer is not formed. The capacitive coupling decreases between the source and drain extension regions (32, 34) and the conductive gate portion 86 since the capacitance is inversely proportional to the increased distance. This capacitance reduction occurs even when there is no cavity 44 formed because there is no recess of gate dielectric 20 and/or metal gate portion 22 so that the length of dielectric segment 38C is zero. The cavity 44 between the source and drain extension regions (32, 34) and the conductive gate portion 86 provides a further decrease of the capacitive coupling between the source and drain extension regions (32, 34) and the conductive gate portion 86 since the dielectric constant of vacuum or air is equal to, or substantially equal to 1. Thus, the second exemplary semiconductor structure provides reduction in overlap capacitance between the gate electrode 96 and the source and drain extension regions (32, 34).

Referring to FIG. 14A, a variation on the second exemplary semiconductor structure is derived from the second exemplary semiconductor structure by omitting the processing step employed to laterally recess the metal gate portion 22 relative the disposable gate portion 24 (See FIG. 7). Thus, the sidewalls of the metal gate portion 22 and the gate dielectric 20 are substantially vertically coincident with the outer sidewalls of the inner gate spacer 70. The reduced overlap between the conductive gate portion 86 and the source and drain extension regions (32, 34) provided reduced overlap capacitance. Instead of a dielectric liner 38 comprising four portions as shown in FIG. 9A, a pair of L-shaped dielectric liners 38L is formed. A vertical portion of each of the L-shaped dielectric liner 38L laterally abuts an outer sidewall of the inner gate spacer 70 and an inner sidewall of the gate spacer 40.

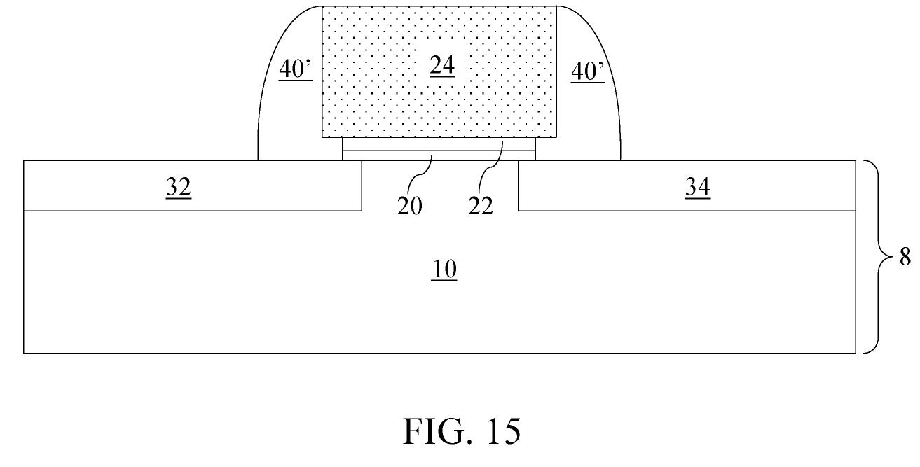

Referring to FIG. 15, a third exemplary semiconductor structure according to a third embodiment of the present invention is derived from the second exemplary semiconductor structure of FIG. 7 by forming a gate spacer 40′. The gate spacer 40′ is formed by deposition of a dielectric material and an anisotropic etch, such as a reactive ion etch, thereof. The deposition of the dielectric material is substantially conformal by selecting a process condition at which the reaction rate is substantially limited by temperature, and not be a reactant supply. Provided suitable deposition conditions are selected, low pressure chemical vapor deposition (LPCVD), plasma enhanced chemical vapor deposition (PECVD), high density plasma chemical vapor deposition (HDPCVD), or rapid thermal chemical vapor deposition (RTCVD) may be employed to effect a substantially conformal deposition of the dielectric material. No cavity is formed on the third exemplary semiconductor structure.

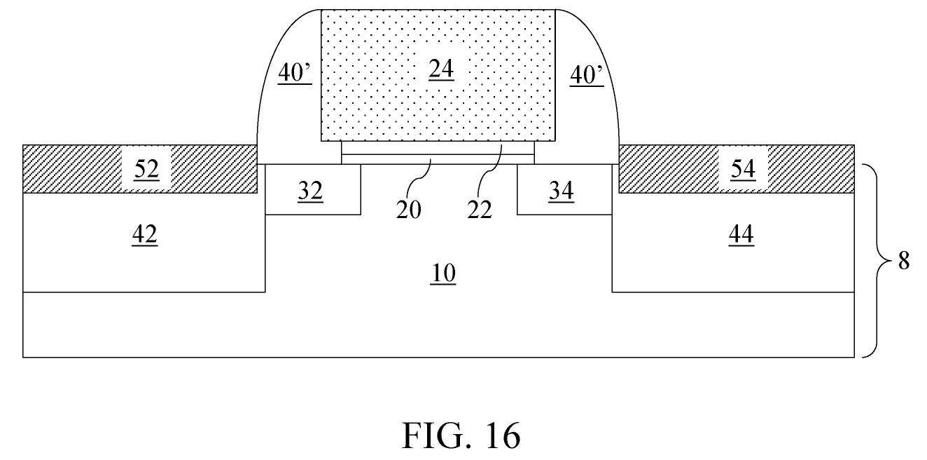

Referring to FIG. 16, a source region 42 and the drain region 44 are formed in the semiconductor layer 10 by ion implantation in the same manner as in the first and second embodiments. A source side metal semiconductor alloy portion 52 and a drain side metal semiconductor alloy portion 54 are formed on the source region 42 and the drain region 44, respectively, by reacting a metal with exposed portions of the semiconductor materials in the semiconductor substrate 8. Preferably, no metal semiconductor alloy portion is formed on the disposable gate portion 24, which may be effected by selection of material that does not form a metal semiconductor alloy for the disposable gate portion 24 or by masking of the disposable gate portion 24 to prevent formation of a metal semiconductor alloy thereupon.

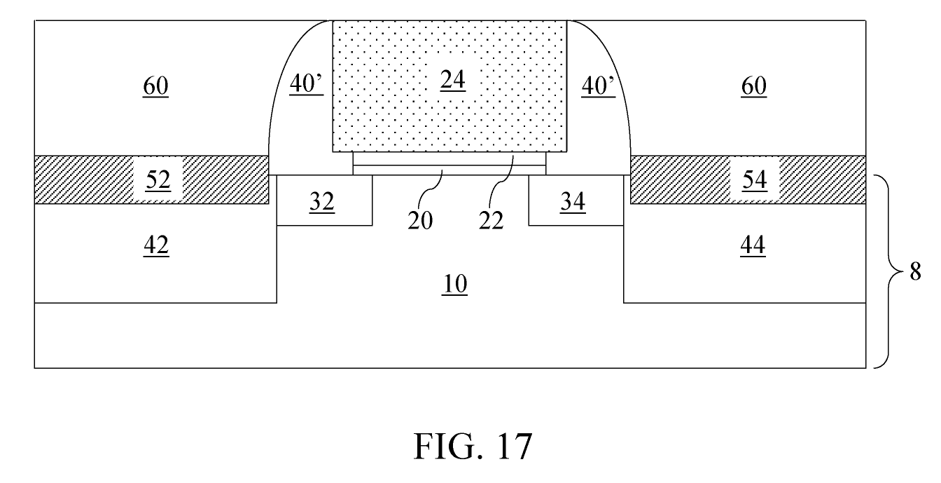

Referring to FIG. 17, a dielectric layer 60 is deposited over the entirety of the top surfaces of the second exemplary semiconductor structure, i.e., over the disposable gate portion 24, the gate spacer 40, the source side metal semiconductor alloy portion 52, and the drain side metal semiconductor alloy portion 54 in the same manner as in the second embodiment. The dielectric layer 60 comprises a dielectric material such as silicon oxide, silicon nitride, silicon oxynitride, or a combination thereof. The dielectric layer 60 is subsequently planarized to form a substantially planar top surface in the same manner as in the second embodiment.

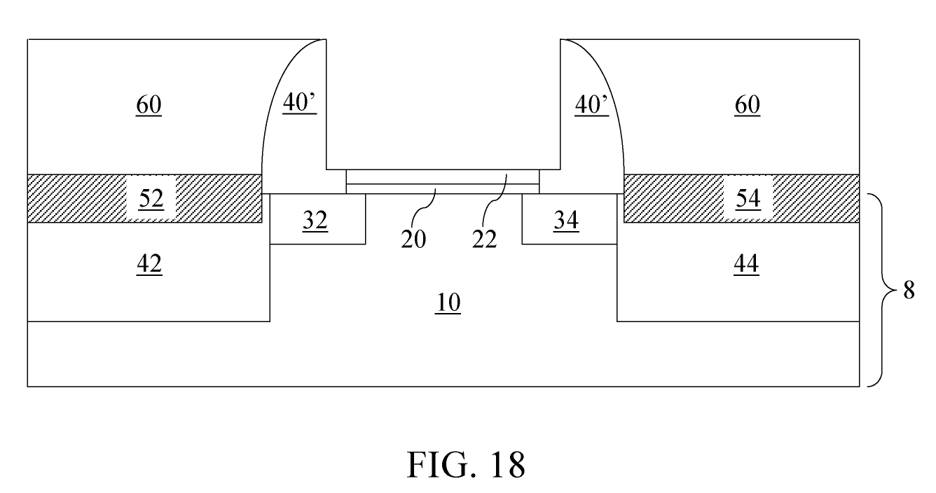

Referring to FIG. 18, the disposable gate portion 24 is removed by an etch that is selective to the materials of the dielectric layer 60, the gate spacer 40′, and the metal gate portion 22. The etch may be a wet etch or a dry etch, and the etch chemistry is optimized to achieve selectivity to the materials on the remaining exposed surfaces.

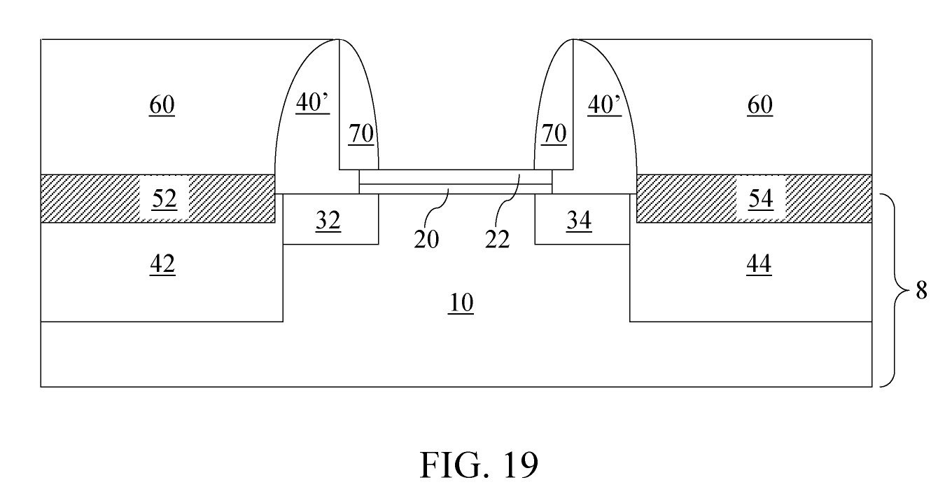

Referring to FIG. 19, an inner gate spacer 70 is formed by a substantially conformal deposition of a dielectric material, followed by a reactive ion etch. The inner gate spacer 70 may comprise the same material as, or a different material from, the gate spacer 40′. For example, the inner gate spacer 70 may comprise silicon oxide. The inner gate spacer 70 overlies the entire periphery of the metal gate portion 20. Further, the lateral width of the inner gate spacer 70, as measured at the bottom of the inner gate spacer 70, is greater than the lateral offset between the substantially vertical sidewalls of the gate spacer 40′ and the substantially vertical sidewalls of the metal gate portion 22. The inner gate spacer 70 is of unitary construction. The inner gate spacer 70 laterally abuts, and is surrounded by, the gate spacer 40′. The outer sidewalls of the inner gate spacer 70 are substantially vertical, and the inner sidewalls of the inner gate spacer 70 may have a convex curvature. The bottom portion of the inner sidewalls of the inner gate spacer 70 may be substantially vertical.

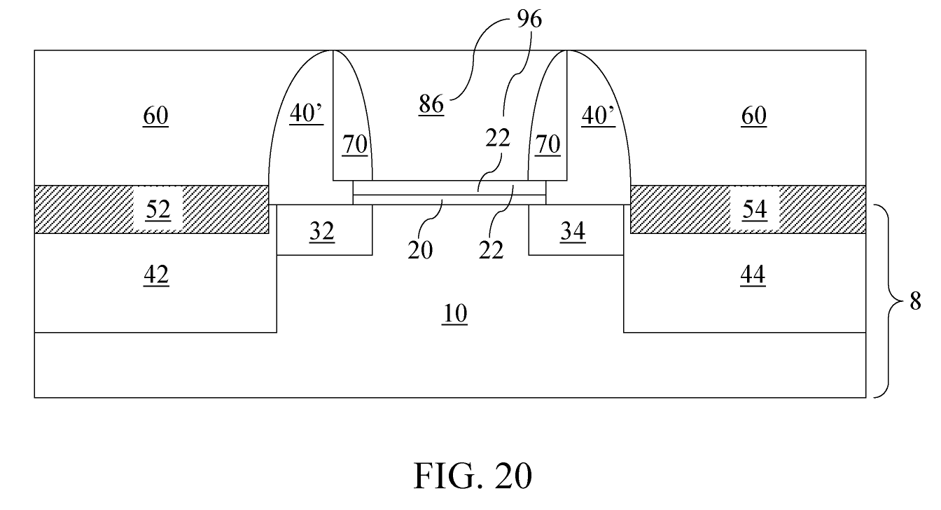

Referring to FIG. 20, a conductive gate portion 86 is formed directly on the metal gate portion 22 and the inner gate spacer 70 by deposition of a conductive material and planarization in the same manner as in the second embodiment. The conductive gate portion 86 and the metal gate portion 22 collectively constitute a gate electrode 96. The threshold voltage of the field effect transistor thus formed is determined by the work function of the metal gate portion 22 in addition to the dopant concentration, external stress, the material, and the crystallographic orientations of the semiconductor layer 11.

Due to the inner gate spacer 70, the distance between the source and drain extension regions (32, 34) and the conductive gate portion 86 is increased in comparison to prior art structures in which an inner gate spacer is not formed. Thus, the third exemplary semiconductor structure provides reduction in overlap capacitance between the gate electrode 96 and the source and drain extension regions (32, 34).

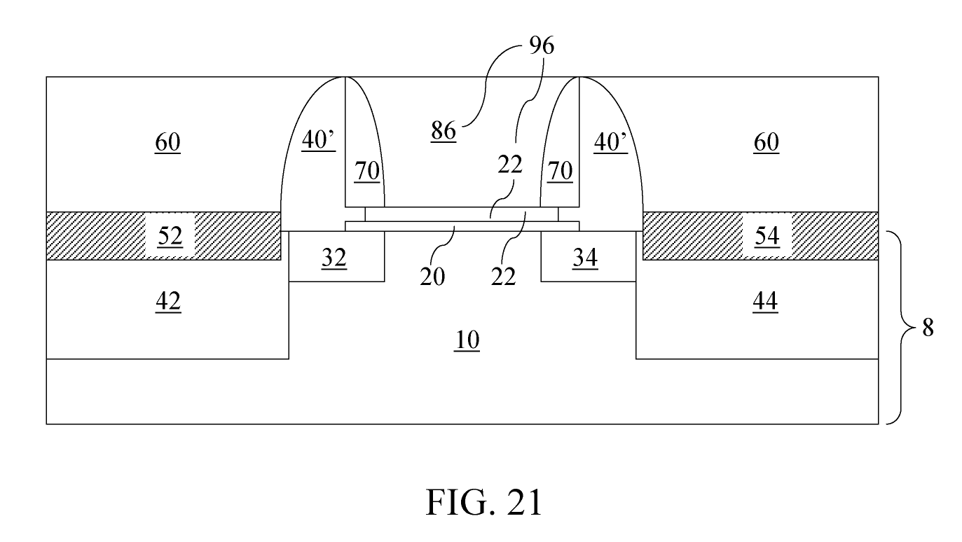

Referring to FIG. 21, a first variation on the third exemplary semiconductor structure is derived from the third exemplary semiconductor structure by modifying the processing step employed to laterally recess the metal gate portion 22 relative to the disposable gate portion 24 (See FIG. 7). Specifically, the metal gate portion 22 is laterally recessed selective to the gate conductor 26 and the gate dielectric 20. The distance of the lateral recess may be from about 0.5 nm to about 10 nm, and typically from about 1 nm to about 5 nm, although lesser and greater distances are contemplated herein also. The gate dielectric 20 is not laterally recessed. Preferably, the sidewalls of the gate conductor 26 and the gate dielectric 20 are substantially vertically coincident after the lateral recess. The sidewalls of the metal gate portion 22 are offset from the sidewalls of the gate conductor 26 by the distance of the lateral offset. The gate spacer 40′ has a protrusion that laterally abuts a sidewall of the metal gate portion 22 and vertically abuts the inner gate spacer 70 and the gate dielectric 20.

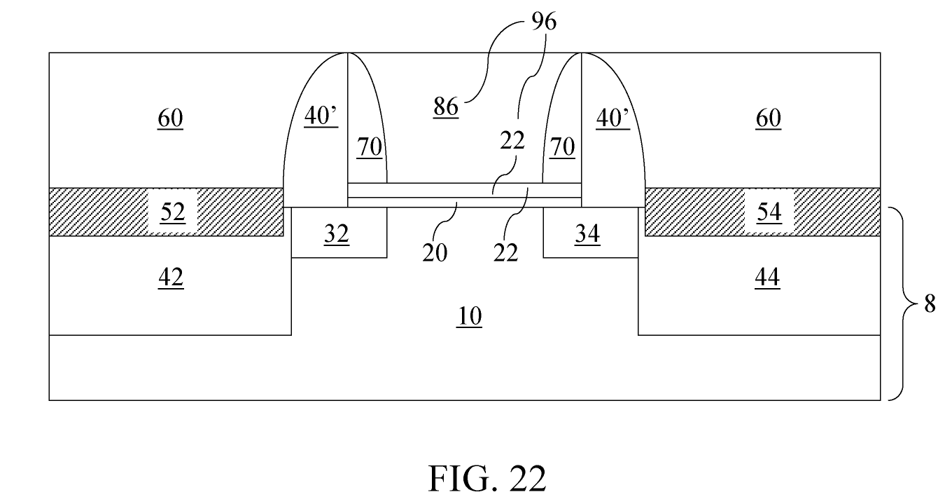

Referring to FIG. 22, a second variation on the third exemplary semiconductor structure is derived from the third exemplary semiconductor structure by omitting the processing step employed to laterally recess the metal gate portion 22 relative the disposable gate portion 24 (See FIG. 7). Thus, the sidewalls of the metal gate portion 22 and the gate dielectric 20 are substantially vertically coincident with the outer sidewalls of the inner gate spacer 70. The reduced overlap between the conductive gate portion 86 and the source and drain extension regions (32, 34) provided reduced overlap capacitance.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A metal-oxide-semiconductor field effect transistor (MOSFET) structure comprising:
a gate dielectric abutting and overlying a body portion, a source extension region, and a drain extension region in a semiconductor substrate;
a metal gate portion vertically abutting said gate dielectric portion;
a gate conductor vertically abutting said metal gate portion;
a gate spacer comprising a dielectric material and laterally abutting said gate conductor and vertically abutting said source extension region or said drain extension region; and
a cavity enclosed by said metal gate portion, said gate dielectric, said gate conductor, and said gate spacer.

2. The MOSFET structure of claim 1, wherein said gate conductor directly overlies an entirety of said cavity.

3. The MOSFET structure of claim 1, wherein sidewalls of said metal gate portion and sidewalls of said gate dielectric are substantially vertically coincident and offset from sidewalls of said gate conductor.

4. The MOSFET structure of claim 1, wherein said cavity separates said gate spacer from said metal gate portion and said gate dielectric.

5. The MOSFET structure of claim 1, wherein sidewalls of said gate conductor and sidewalls of said gate dielectric are substantially vertically coincident and offset from sidewalls of said metal gate portion.

6. A metal-oxide-semiconductor field effect transistor (MOSFET) structure comprising:
a gate dielectric abutting and overlying a body portion, a source extension region, and a drain extension region in a semiconductor substrate;
a metal gate portion vertically abutting said gate dielectric portion;
a dielectric liner vertically abutting said source extension region or said drain extension region and laterally abutting said gate dielectric and said metal gate portion; and
an inner gate spacer overlying an entire periphery of said metal gate portion.

7. The MOSFET structure of claim 6, wherein said dielectric liner comprises:
a first horizontal dielectric liner portion vertically abutting said source extension region or said drain extension region;
a first vertical dielectric liner portion laterally abutting said gate dielectric and said metal gate portion;
a second horizontal dielectric liner portion directly adjoined to said first vertical dielectric liner portion and abutting a bottom surface of said inner gate spacer; and
a second vertical dielectric liner portion directly adjoined to said second horizontal dielectric liner portion and abutting a substantially vertical sidewall of said inner gate spacer.

8. The MOSFET structure of claim 6, further comprising:
a gate conductor vertically abutting said metal gate portion; and
a gate spacer comprising a dielectric material, overlying said source extension region or said drain extension region, and abutting said dielectric liner.

9. The MOSFET structure of claim 8, further comprising a cavity enclosed by said gate spacer and said dielectric liner.

10. The MOSFET structure of claim 8, wherein sidewalls of said metal gate portion and sidewalls of said gate dielectric are substantially vertically coincident and offset from sidewalls of said gate conductor.

11. A metal-oxide-semiconductor field effect transistor (MOSFET) structure comprising:
a gate dielectric abutting and overlying a body portion, a source extension region, and a drain extension region in a semiconductor substrate;
a metal gate portion vertically abutting said gate dielectric portion;
a gate spacer vertically abutting said source extension region or said drain extension region and laterally abutting said gate dielectric and said metal gate portion; and
an inner gate spacer overlying an entire periphery of said metal gate portion.

12. The MOSFET structure of claim 11, further comprising:
a gate conductor vertically abutting said metal gate portion; and
a gate spacer comprising a dielectric material, vertically abutting said source extension region or said drain extension region, and laterally abutting said dielectric liner.

13. The MOSFET structure of claim 11, wherein sidewalls of said metal gate portion and sidewalls of said gate dielectric are substantially vertically coincident and offset from sidewalls of said inner gate spacer.

14. The MOSFET structure of claim 11, wherein a bottom surface of said inner gate spacer overlies an entire periphery of said metal gate portion.

15. The MOSFET structure of claim 11, wherein said gate spacer comprises:
a first horizontal gate spacer surface vertically abutting said source extension region or said drain extension region;
a first vertical gate spacer surface laterally abutting said gate dielectric and said metal gate portion;
a second horizontal gate spacer surface directly adjoined to said first vertical gate spacer surface and abutting a bottom surface of said inner gate spacer; and
a second vertical gate spacer surface directly adjoined to said second horizontal gate spacer surface and abutting a substantially vertical sidewall of said inner gate spacer.

16. A method of forming a semiconductor structure comprising:
forming a stack of a gate dielectric, a metal gate portion, and one of a gate conductor and a disposable gate portion on a semiconductor substrate, wherein sidewalls of said gate dielectric, said metal gate portion, and one of said gate conductor and said disposable gate portion are substantially vertically coincident;
laterally recessing a sidewall of said metal gate portion relative to a sidewall of said one of said gate conductor and said disposable gate portion;
forming a source extension region and a drain extension region underlying said metal gate portion; and
forming a gate spacer on said gate dielectric, said one of said gate conductor and said disposable gate portion, said source extension region, and said drain extension region.

17. The method of claim 16, further comprising forming a cavity encapsulated by said gate dielectric, said metal gate portion, said gate spacer, and said gate conductor, wherein said gate spacer is formed directly on said gate dielectric, said one of said gate conductor and said disposable gate portion, said source extension region, and said drain extension region.

18. The method of claim 16, further comprising:
forming a dielectric liner laterally abutting said gate dielectric, said metal gate portion, and said disposable gate portion; and
forming a cavity encapsulated by said dielectric liner and said gate spacer, wherein said disposable gate portion overlies an entirety of said cavity.

19. The method of claim 18, further comprising:
forming a dielectric layer over said disposable gate portion;
planarizing said dielectric layer, wherein a top surface of said dielectric layer is substantially coplanar with a top surface of said disposable gate portion;
removing said gate disposable gate portion;
forming an inner gate spacer overlying an entire periphery of said metal gate portion, wherein a sidewall of said metal gate portion directly adjoins a bottom surface of said inner gate spacer; and
forming a conductive gate portion directly on said metal gate portion.

20. The method of claim 16, wherein said gate spacer is formed directly on said gate dielectric, said metal gate portion, said one of said gate conductor and said disposable gate portion, said source extension region, and said drain extension region, and said method further comprising:
forming a dielectric layer over said disposable gate portion;
planarizing said dielectric layer, wherein a top surface of said dielectric layer is substantially coplanar with a top surface of said disposable gate portion;
removing said gate disposable gate portion;
forming an inner gate spacer overlying an entire periphery of said metal gate portion, wherein a sidewall of said metal gate portion directly adjoins a bottom surface of said inner gate spacer; and
forming a conductive gate portion directly on said metal gate portion.
